(19) United States
(12) Patent Application Publication
(10) Pub. No.: US 2012/0326173 A1
(43) Pub. Date: Dec. 27, 2012

(54) LIGHT EMITTING DIODE ELEMENT, METHOD OF FABRICATION AND LIGHT EMITTING DEVICE

(76) Inventors: Wen-Chia LIAO, Taoyuan County (TW); Li-Fan Lin, Taoyuan County (TW); Ching-Chuan Shiue, Taoyuan County (TW); Shih-Peng Chen, Taoyuan County (TW)

(21) Appl. No.: 13/364,963

(22) Filed: Feb. 2, 2012

(30) Foreign Application Priority Data
Jun. 27, 2011 (TW) 100122365

(51) Int. Cl. H01L 33/22; H01L 33/36; H01L 33/08

(52) U.S. Cl. 257/88; 257/98; 438/29; 257/E33.067; 257/E33.062

(57) ABSTRACT

A light emitting diode comprises a multi-layer semiconductor, a first electrode and a second electrode. The multi-layer semiconductor has a light emitting active layer substantially perpendicular to the predetermined surface, a first semiconductor layer located on a surface of the light emitting active layer and a second semiconductor layer located on an opposite surface of the light emitting active layer. The first electrode is provided adjacent to and electrically connect to the first semiconductor layer. The second electrode is provided adjacent to and electrically connect to the second semiconductor layer. In addition, a method of fabricating LED element and a light emitting device having the LED elements are provided.

### BACKGROUND OF THE INVENTION

1. Field of the Invention

This invention generally relates to a light emitting diode (LED) element, and in particular to an LED element having light emitting active layer perpendicular to and self-standing on the mounting surface of a base and to methods of fabricating the same.

2. Description of Prior Art

LED elements have widely used as various types of light sources for their advantages of high speed reaction, long life and small. LED elements have light emitting dies, fabricated by semiconductor manufacturing process, welded to the base thereof to electrically connect with external power source. The light emitting dies mainly comprise a substrate, a p-type semiconductor layer, a light emitting active layer and an n-type semiconductor layer formed on the substrate. When electrons and holes flow into the light emitting active layer and when an electron meets a hole, the light emitting active layer may release a photon due to re-combination of an electron meets a hole. These photons are the source of light emitted from the light emitting dies.

These photons produced from the light emitting active layer are emitted in all directions therefrom. In a conventional package process, the light emitting dies are horizontally mounted on the base, so that electrodes of the light emitting dies may electrically connect to contact pads of the base by wire-bonding or flip-chip. Such manner the light emitting active layer of the light emitting dies is parallel to the mounting surface of the base, and caused the photons emitted from lower surface of the light emitting active layer move towards the base that could hardly contribute to the overall light emitting efficiency of the LED elements. Even though a reflective layer is formed below the light emitting active layer to reflect the photons towards upper side, the contribution to the overall light emitting efficiency of the LED elements is still low because a long travelling path of the photon may cause a loss of the photons absorbed by the light emitting dies or package material.

Therefore, U.S. Pat. No. 7,847,306 disclosed an LED element having light emitting dies vertically mounting on a base so that the light emitting active layer perpendicular to a mounting surface of the base whereby the photons emitted from two surfaces of the light emitting active layer may emit from two sides of the light emitting die. Therefore, the overall light emitting efficiency of the LED elements may be enhanced.

However, the above LED element has two electrodes on a surface of the same side of the light emitting die, whereas the electrodes may obstruct the light to cause a different light emission amount of the two surfaces of the light emitting die. It is required to form an additional opaque mask layer on the opposite surface for balancing the light emission amount of the two surfaces of the light emitting die, but it is inevitable to reduce the overall light emission amount. Also, in order to increase the effective light emitting region, comb electrodes are generally used to have a uniform electricity distribution, but the comb electrodes having a larger region occupying the light emitting region may cause a serious imbalance of the different light emission amount of the two sides of the light emitting die.

In addition, it is difficult for the LED element to stand on the mounting surface by its thin edge, and the LED element has two electrodes on a surface of the same side of the light emitting die that may cause its imbalance so that the LED element is not capable of self-standing on the mounting surface. Therefore, it is required to use additional tools for fixing the LED element on the relative position of the base when the LED element is mounted and welded on the mounting surface. Also, it is hard to electrically connect the LED element with the base by the general surface mount technology.

### SUMMARY OF THE INVENTION

Therefore, it is an object of this invention to provide an LED element self-standing on the mounting surface of a base and methods of fabricating the same.

The object described above is achieved by an LED element for mounting on a predetermined surface. The LED element comprises a multi-layer semiconductor, a first electrode and a second electrode. The multi-layer semiconductor has a light emitting active layer substantially perpendicular to the predetermined surface, a first semiconductor layer located on a surface of the light emitting active layer and a second semiconductor layer located on an opposite surface of the light emitting active layer. The first electrode is provided adjacent to and electrically connect to the first semiconductor layer. The second electrode is provided adjacent to and electrically connect to the second semiconductor layer.

There is disclosed herein a method of fabricating LED element comprises: epitaxially growing a multi-layer semiconductor on a light transmissive substrate, wherein the multi-layer semiconductor has a first semiconductor layer located on the light transmissive substrate, a light emitting active layer located on the first semiconductor layer and a second semiconductor layer located on the light emitting active layer; forming a light transmissive insulator to cover the multi-layer semiconductor; forming a first electrode to electrically connect the light transmissive substrate with the first semiconductor layer; forming a second electrode to electrically connect the light transmissive insulator with the second semiconductor layer; and forming a first end surface of the first electrode and a second end surface of the second electrode to align the first end surface.

There is disclosed herein another method of fabricating LED element comprises: epitaxially growing a multi-layer semiconductor on a growing substrate, wherein the multi-layer semiconductor has a first semiconductor layer located on the light transmissive substrate, a light emitting active layer located on the first semiconductor layer and a second semiconductor layer located on the light emitting active layer; forming a light transmissive insulator to cover the multi-layer semiconductor; replacing the growing substrate by a light transmissive substrate; forming a first electrode to electrically connect the light transmissive substrate with the first semiconductor layer; forming a second electrode to electrically connect the light transmissive insulator with the second semiconductor layer; and forming a first end surface of the first electrode and a second end surface of the second electrode to align the first end surface.

Additionally, it is another object of this invention to provide a light emitting device having the above LED elements.

The light emitting device of the invention can be mounted on a predetermined surface. The light emitting device comprises at least two LED elements and a light guiding layer. The light guiding layer is provided between two LED elements on the predetermined surface. The light guiding layer has a light emitting face and two light incident faces provided adjacent the light emitting face facing two adjacent LED elements respectively.

### BRIEF DESCRIPTION OF THE DRAWINGS

FIG. 1a shows a sectional view of LED element according to the invention.

FIG. 1b shows a sectional view of LED element according to a variation of the invention.

FIG. 2a-2i shows a schematic view of steps of method for fabricating LED element according to FIG. 1.

FIG. 3 shows a sectional view of LED element according to the invention.

FIG. 4a-4e shows a schematic view of steps of method for fabricating LED element according to FIG. 3.

FIG. 5a shows a schematic view of LED element mounting on PCB of the invention.

FIG. 5b shows a schematic view of LED element mounting on PCB with an inner covering body of the invention.

FIG. 6 shows a schematic view of LED element mounting on PCB of the invention.

FIG. 7 shows a sectional view of LED element according to the invention.

FIG. 8 shows a sectional view of LED element according to the invention.

FIG. 9a-9j shows a schematic view of steps of method for fabricating LED element according to FIG. 8.

FIG. 10 shows a sectional view of LED element according to the invention.

FIG. 11 shows a sectional view of LED element according to the invention.

FIG. 12 shows a sectional view of LED element according to the invention.

FIG. 13 shows a sectional view of the light emitting device according to the invention.

### DETAILED DESCRIPTION OF THE INVENTION

The technical contents, detailed explanation and effect of the present invention may be further understood with reference to the following description and the appended drawings.

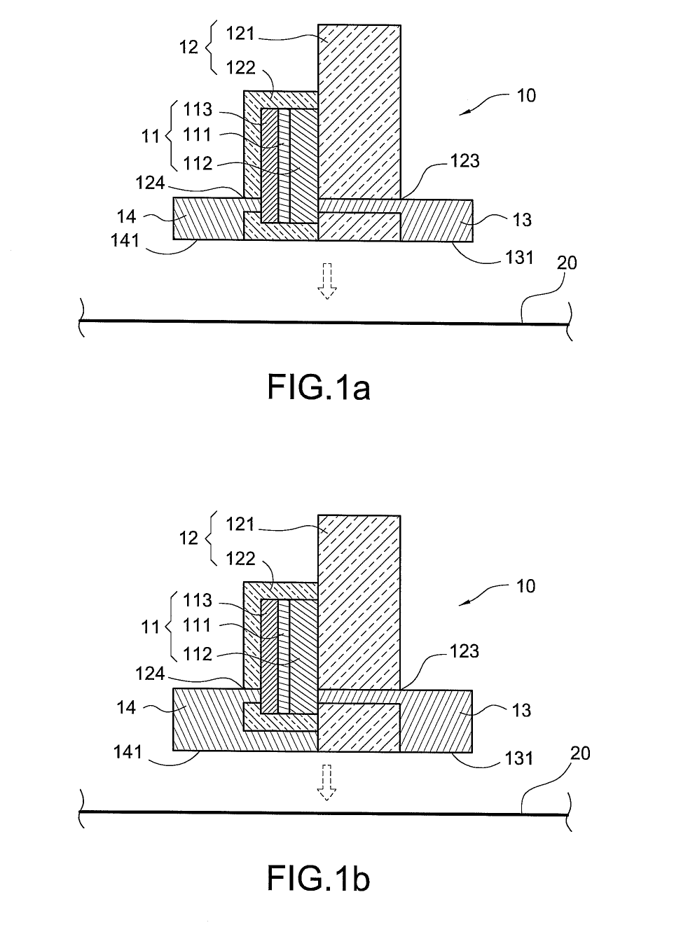

Please refer to FIG. 1a, which shows a sectional view of a first preferred example of an LED element according to the invention. The LED element 10 is used for mounting on a predetermined surface 20. The predetermined surface 20 may be a base or a mounting surface of a printed circuit board (PCB). The LED element 10 may self-stand on the predetermined surface 20. As shown in FIG. 1a, the LED element 10 mainly comprises a multi-layer semiconductor 11, a light transmissive substrate 121, a light transmissive insulator 122, a first electrode 13 and a second electrode 14.

The multi-layer semiconductor 11 has a light emitting active layer 111 substantially perpendicular to the predetermined surface 20, a first semiconductor layer 112 located on a surface of the light emitting active layer 111 and a second semiconductor layer 113 located on an opposite surface of the light emitting active layer 111. Specifically, the first semiconductor layer 112 is an n-type semiconductor material and the second semiconductor layer 113 is a p-type semiconductor material.

In the example, the light transmissive substrate 121 and the light transmissive insulator 122 are both used to cover the multi-layer semiconductor 11. The light transmissive substrate 121 is adjacent the first semiconductor layer 112 and exposed a first through hole 123 of the first semiconductor layer 112. The light transmissive insulator 122 may cover the multi-layer semiconductor 11 and expose a second through hole 124 of the second semiconductor layer 113.

The first electrode 13 may electrically connect to the first semiconductor layer 112 by the light transmissive substrate 121. Specifically, in the example, an end of the first electrode 13 connects to the first semiconductor layer 112 by the first through hole 123, and the other end of the first electrode 13 extends towards the predetermined surface 20 and the first electrode 13 has a first end surface 131 facing the predetermined surface 20.

The second electrode 14 electrically connects to the second semiconductor layer 113. Preferably, the first electrode 13 substantially aligns the second electrode 14, and the first electrode 13 and the second electrode 14 respectively locate on two opposite sides of the multi-layer semiconductor 11. Specifically, in the example, an end of the second electrode 14 connects to the second semiconductor layer 113 by the second through hole 124, and the other end of the second electrode 14 extends towards the predetermined surface 20 and the second electrode 14 has a second end surface 141 facing the predetermined surface 20.

Also, the first end surface 131 is directed to substantially align the second end surface 141, that is to say, the first end surface 131 and the second end surface 141 are directed to substantially locate on the same plane for contacting the predetermined surface 20. Preferably, the first end surface 131 and the second end surface 141 are further directed to be perpendicular to the light emitting active layer 111 so that the multi-layer semiconductor 11 may perpendicularly mount on the predetermined surface 20.

The LED element 10 can be supported from two opposite directions by the first electrode 13 and the second electrode 14 which are located on two opposite sides of the LED element 10 to stand on the predetermined surface 20 without any additional auxiliary tool. Also, the first end surface 131 and the second end surface 141 align with each other so that the LED element 10 can more stably stand on the predetermined surface 20. In addition, when supplying power to the multi-layer semiconductor 11, the heat produced from the multi-layer semiconductor 11 can dissipate from the first electrode 13 and the second electrode 14 respectively since the first electrode 13 and the second electrode 14 are located on two opposite sides of the multi-layer semiconductor 11. Compared with the prior art of two electrodes locating on the same side, the invention has a preferred heat dissipation efficiency.

FIG. 1b shows a sectional view of LED element according to a variation of the invention. The difference between FIG. 1a and FIG. 1b is that an end of the second electrode 14 connects to the second semiconductor layer 113 by the second through hole 124, but the other end of the second electrode 14 connects to the light transmissive substrate 121 and the second electrode 14 has a second end surface 141 facing the predetermined surface 20.

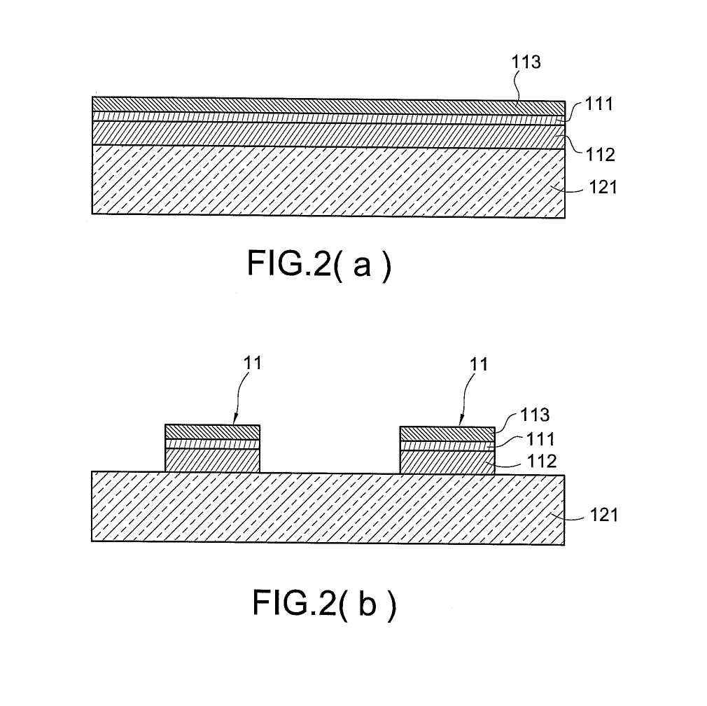

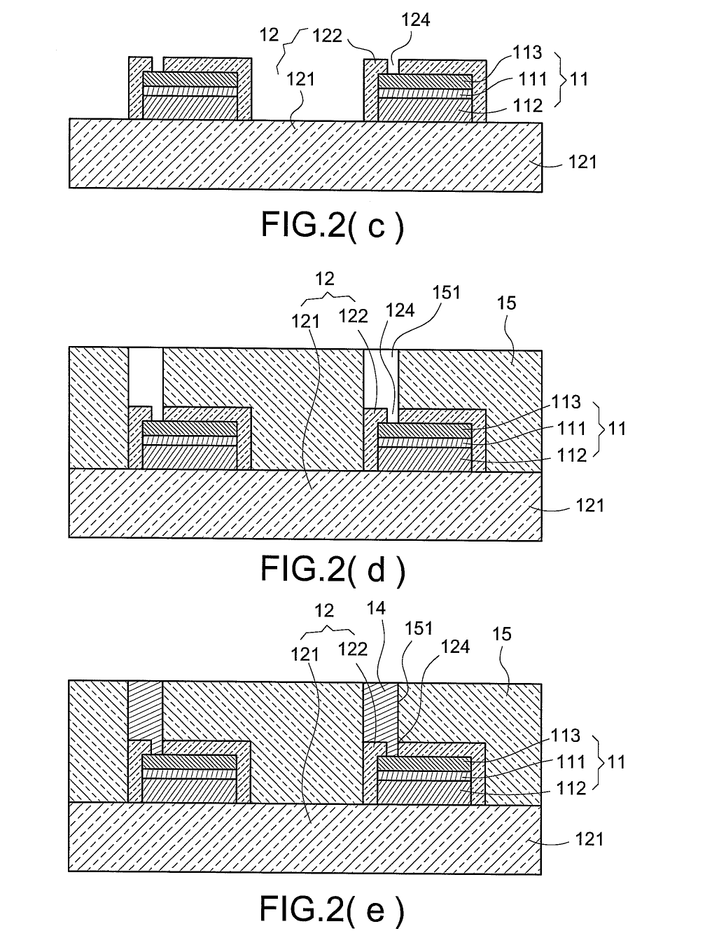

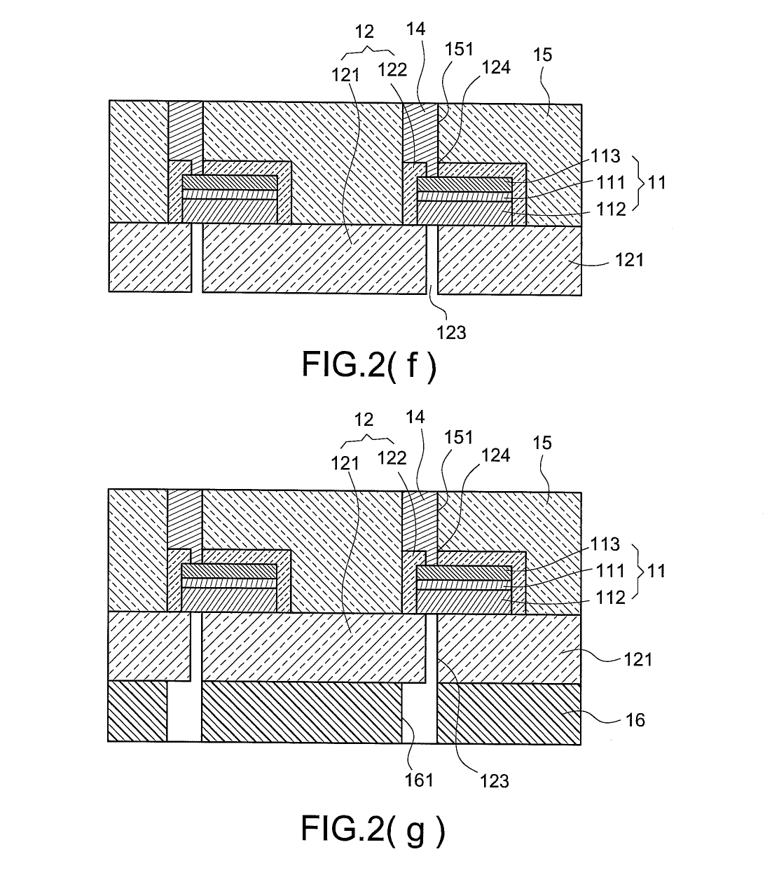

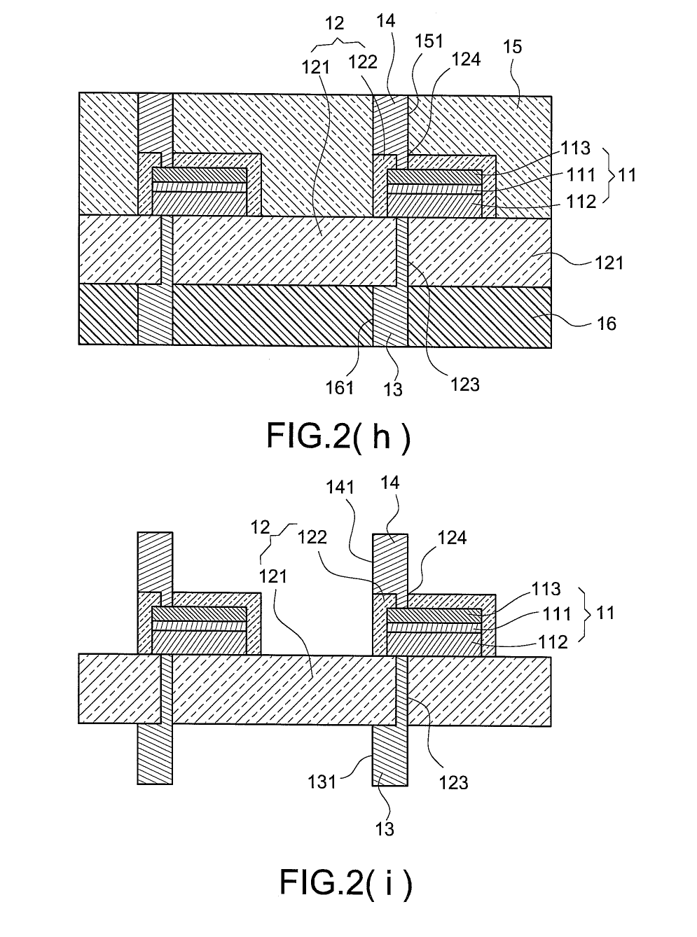

A method of fabricating LED element 10 is described with reference to FIG. 2.

At first, as shown in FIG. 2(a), a first semiconductor layer 112, a light emitting active layer 111 and a second semiconductor layer 113 are epitaxially growing on a light transmissive substrate 121 in sequence. The method of epitaxially growing may be but not limited to organic metal chemical vapor deposition or molecular beam epitaxy.

Next, the epitaxial layers are etched by photolithography and etching process to obtain a plurality of the multi-layer semiconductor 11 located at the light transmissive substrate 121 as shown in FIG. 2(b). The multi-layer semiconductor 11 has a first semiconductor layer 112 located on the light transmissive substrate 121, a light emitting active layer 111 located on the first semiconductor layer 112 and a second semiconductor layer 113 located on the light emitting active layer 111.

Next, as shown in FIG. 2(c), a light transmissive insulator 122 is formed to cover the multi-layer semiconductor 11 by thin film process. Also, a second through hole 124 is formed in the light transmissive insulator 122 to expose the second semiconductor layer 113.

Next, as shown in FIG. 2(d), a first mask layer 15 is formed on the light transmissive substrate 121 and the multi-layer semiconductors 11. The first mask layer 15 has a plurality of first via holes 151 to communicate the second through holes 124 respectively. The first mask layer 15 may be made of but not limited to photoresist material by photolithography process.

As shown in FIG. 2(e), the second electrode 14 for electrically connecting the second semiconductor layer 113 is formed by electroplating or electroforming process in the first via holes 151 and the second through holes 124.

Next, as shown in FIG. 2(f), a plurality of first through holes 123 are formed in the light transmissive substrate 121 to expose the first semiconductor layer 112. Next, as shown in FIG. 2(g), a second mask layer 16 is formed on a low surface of the light transmissive substrate 121. The second mask layer 16 has a plurality of second via holes 161 to communicate the first through holes 123 respectively. The second mask layer 16 may be made of but not limited to photoresist material by photolithography process. It should be noted that the second via holes 161 align with the first via holes 151, and at least one of lateral borders of the second via holes 161 align with a lateral border of the first via holes 151 in FIG. 2(g).

Next, as shown in FIG. 2(h), the light transmissive substrate 121 through which the first electrode 13 for electrically connecting the first semiconductor layer 112 is formed by electroplating or electroforming process in the second via holes 161 and the first through holes 123.

Next, the first mask layer 15 and the second mask layer 16 are removed to obtain a state as shown in FIG. 2(i). Because the second via holes 161 substantially align with the first via holes 151, and at least one of lateral borders of the second via holes 161 align with a lateral border of the first via holes 151 so that the first electrode 13 formed with the second via hole 161 may substantially align with the second electrode 14 formed with the first via hole 151. Also, the first electrode 13 may form a first end surface 131 away from one side of the multi-layer semiconductors 11, that is to say, the first end surface 131 and the second end surface 141 locate on the same plane. Finally, the LED element 10 shown as FIG. 1 is obtained by cutting the light transmissive substrate 121 along the connecting line of the first end surface 131 and the second end surface 141.

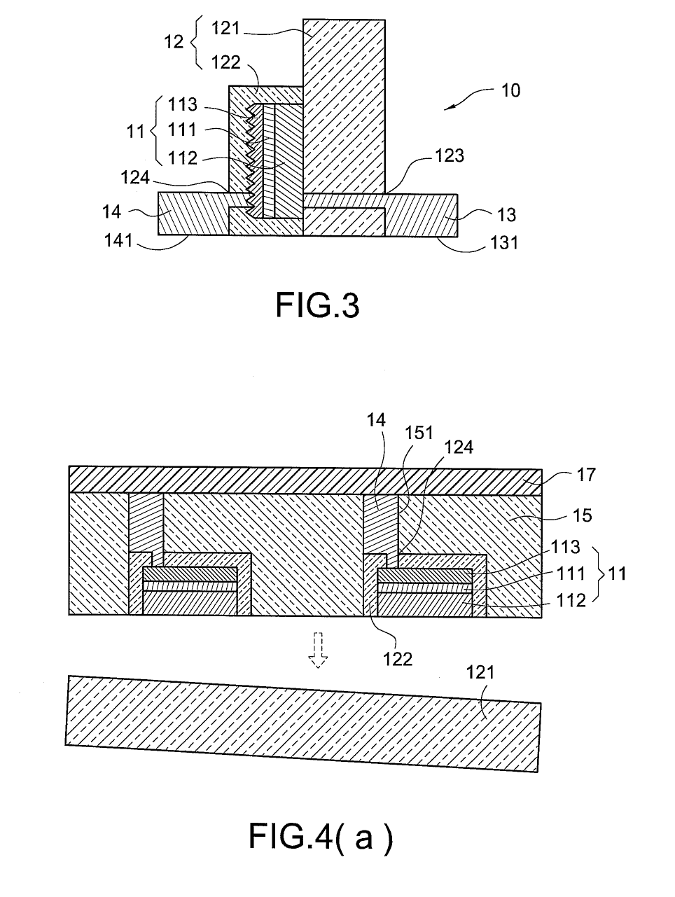

FIG. 3 shows another example of LED element according to the invention. The LED element has a similar structure except that the second semiconductor 113 has a texture surface or at least a part of surface having texture structure adjacent the light transmissive insulator 122. The light emitting output may be increased due to the texture surface or texture structure. Further, the surface of the light transmissive substrate 121 adjacent the first semiconductor layer 112 may be a texture surface. The light transmissive substrate 121 can be Sapphire substrate. However a high light transmissive substrate can be used in an LED element of the invention in order to enhance the light emitting output.

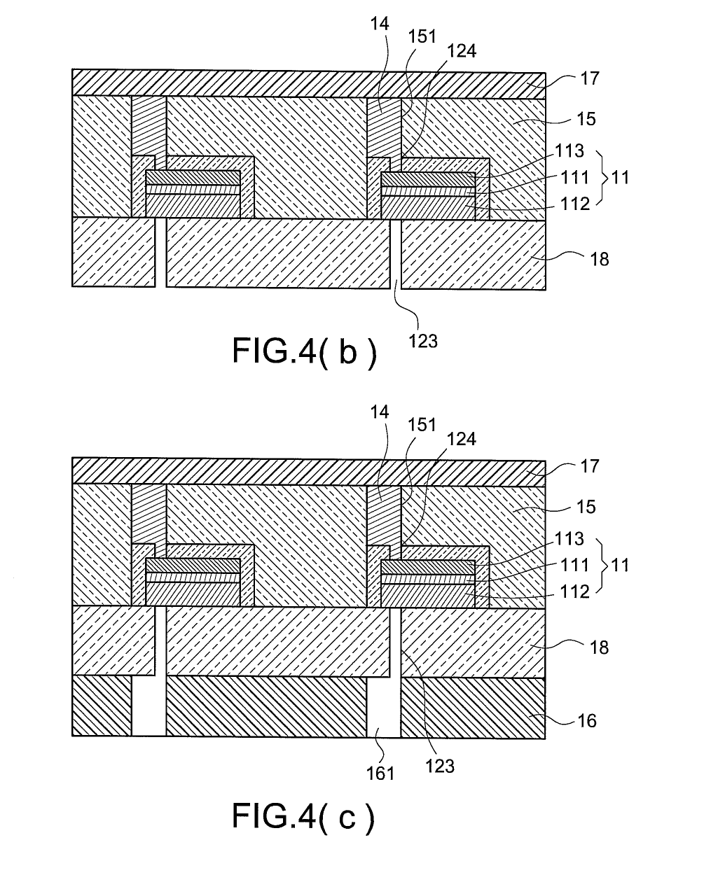

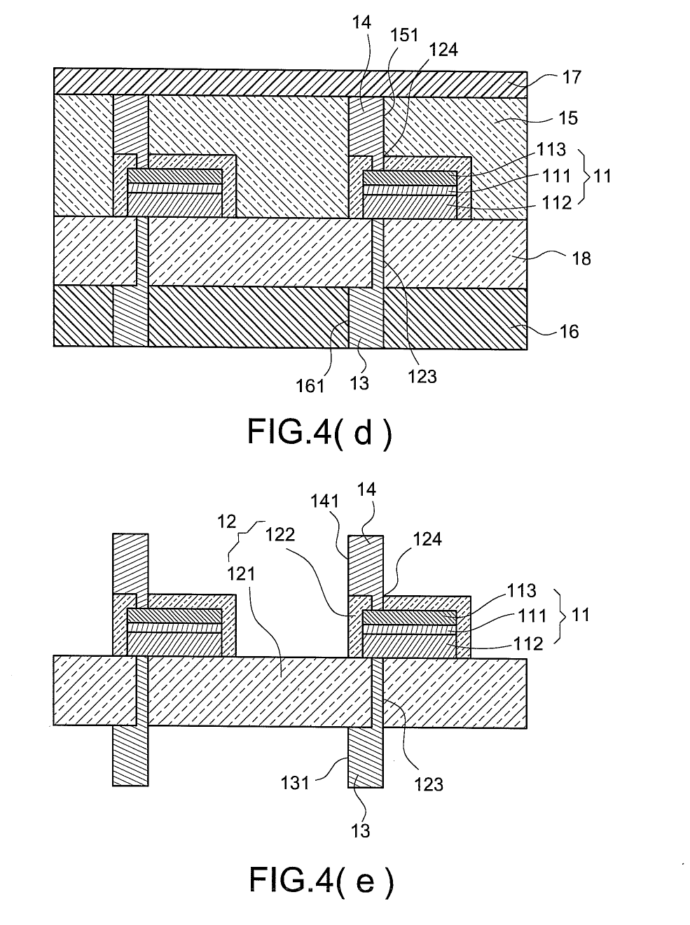

The method has the same steps prior to and including FIG. 2(e), after forming the second electrode 14 through the first mask layer 15, and then as shown in FIG. 4(a), a temporary substrate 17 is bonded to the first mask layer 15, and alternatively, a temporary substrate 17 can be formed by electroplating a thick layer on the first mask layer 15. Moreover, another example of the method has the same steps prior to and including FIG. 2(d), a first mask layer 15 is formed on the light transmissive substrate 121 and the multi-layer semiconductors 11, and then as shown in FIG. 4(a), the second electrode 14 for electrically connecting the second semiconductor layer 113 can be formed in the first via holes 151 and the second through holes 124 as well as a temporary substrate 17 can be formed on the first mask layer 15 by electroplating or electroforming process. Then, the original light transmissive substrate 121 is separated from the low surface of the multi-layer semiconductor 11 and the first mask layer 15. The separation may be achieved by but not limited to laser lift off or etching. Also, as shown in FIG. 4(b), a high light transmissive substrate 18 is fixed on the low surface of the multi-layer semiconductor 11 and the first mask layer 15. The light transmissive substrate 18 has a plurality of the first through holes 123. The first through holes 123 may be pre-formed on the light transmissive substrate 18. Alternatively, the first through holes 123 may be formed after the light transmissive substrate 18 is fixed on the low surface of the multi-layer semiconductor 11 and the first mask layer 15.

Next, as shown in FIG. 4(c) to FIG. 4(e), the first electrodes 13 are formed by using the second mask layer 16. The process is the same to FIG. 2(g) to FIG. 2(i) so that the description is omitted herein. In FIG. 4(e), the temporary substrate 17 is removed with the first mask layer 15 and the second mask layer 16 in the same time.

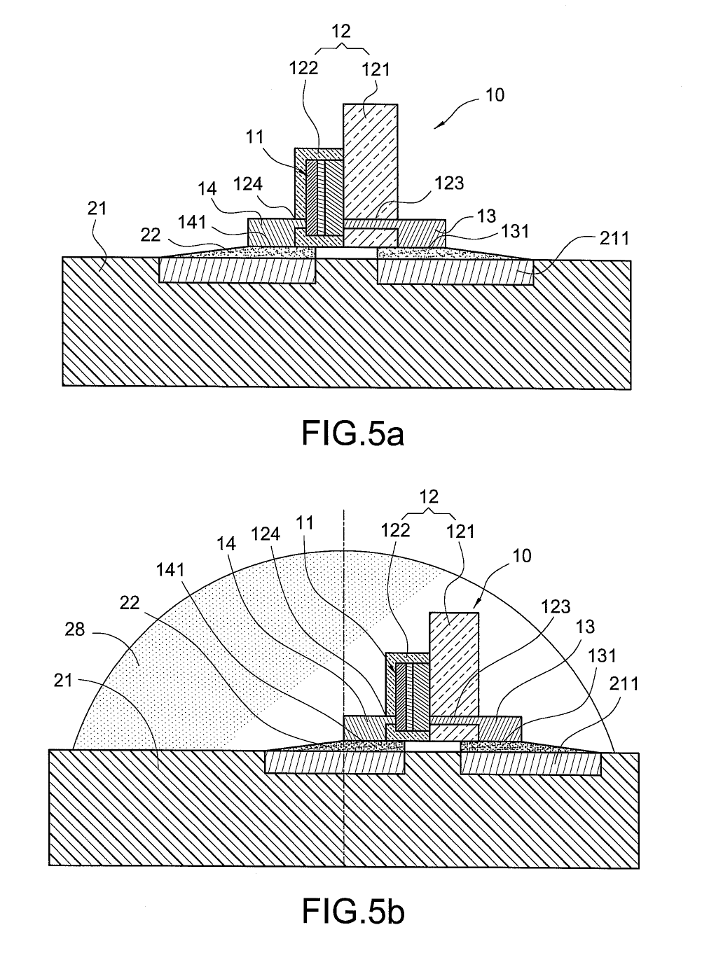

FIG. 5a shows an application example of the LED elements 10. The LED element 10 may self-stand on the PCB 21 by the first end surface 131 and the second end surface 141 with welding material 22 electrically connecting to a welding pad 211 of the PCB 21 in surface mount technology. In addition, FIG. 5b shows another application example of the LED elements 10. Silicone is dotted on the PCB 21 to form an inner covering body 28 slanted towards the light transmissive substrate 121 for balancing the light emitting amount at two sides of the LED element 10.

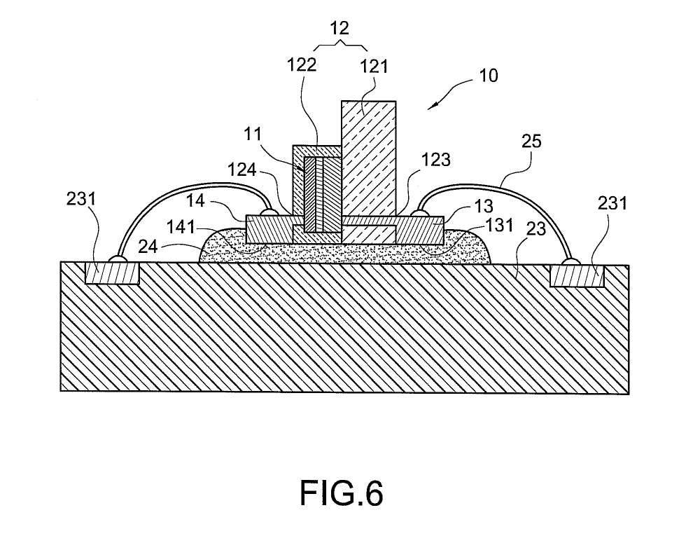

Alternatively, FIG. 6 shows another application example of the LED elements 10. The LED element 10 may self-stand on the PCB 23 by the first end surface 131 and the second end surface 141 with adhesive 24 sticking on the PCB 23 and a wire 25 electrically connecting to a welding pad 231 of the PCB 23.

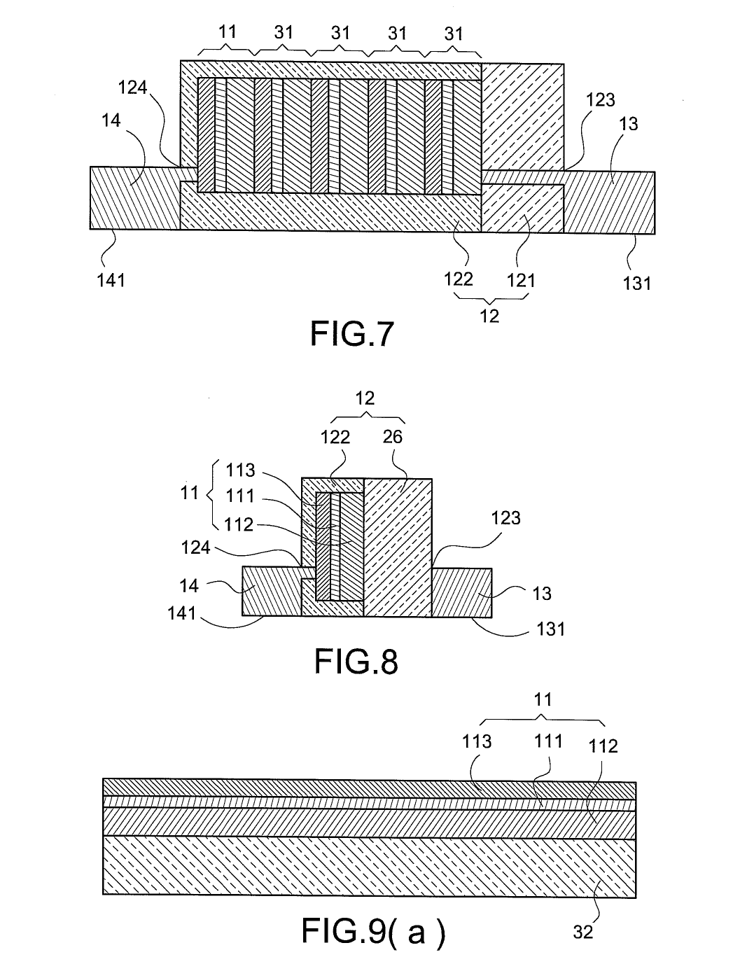

Further, FIG. 7 shows another example of LED elements according to the invention. The LED elements 10 further include at least one multi-layer semiconductor 31 adjacent the multi-layer semiconductor 11. The wavelength of light emitted from multi-layer semiconductor 31 may be or may be not the same to the multi-layer semiconductor 11 thereof. For example, the light emitted from multi-layer semiconductor 31 and the multi-layer semiconductor 11 may include red light, green light and blue light with different wavelength.

Moreover, FIG. 8 shows another example of LED element according to the invention. The LED element has a similar structure except that the light transmissive substrate 121 of FIG. 1 is replaced by a light transmissive conductive substrate 26 of FIG. 8. In particular, the light transmissive conductive substrate 26 of FIG. 8 is adjacent the first semiconductor layer 112, and the light transmissive insulator 122 covers the multi-layer semiconductor 11 and has a through hole 124 to expose the second semiconductor layer 113. The first electrode 13 may electrically connect to the first semiconductor layer 112 by the light transmissive conductive substrate 26, and the second electrode 14 may electrically connect to the second semiconductor layer 113 by the through hole 124

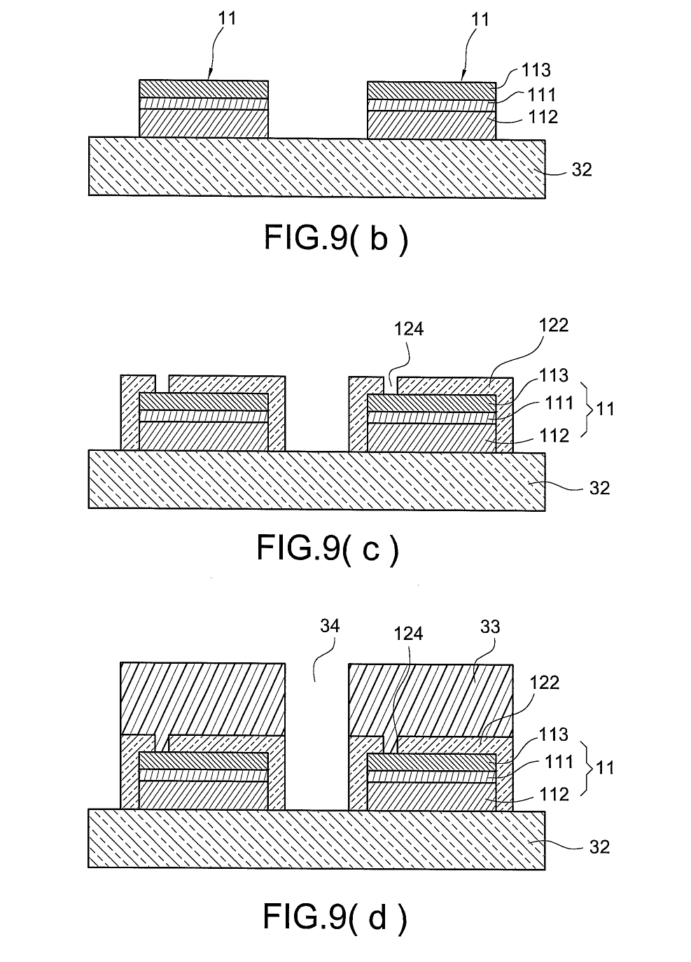

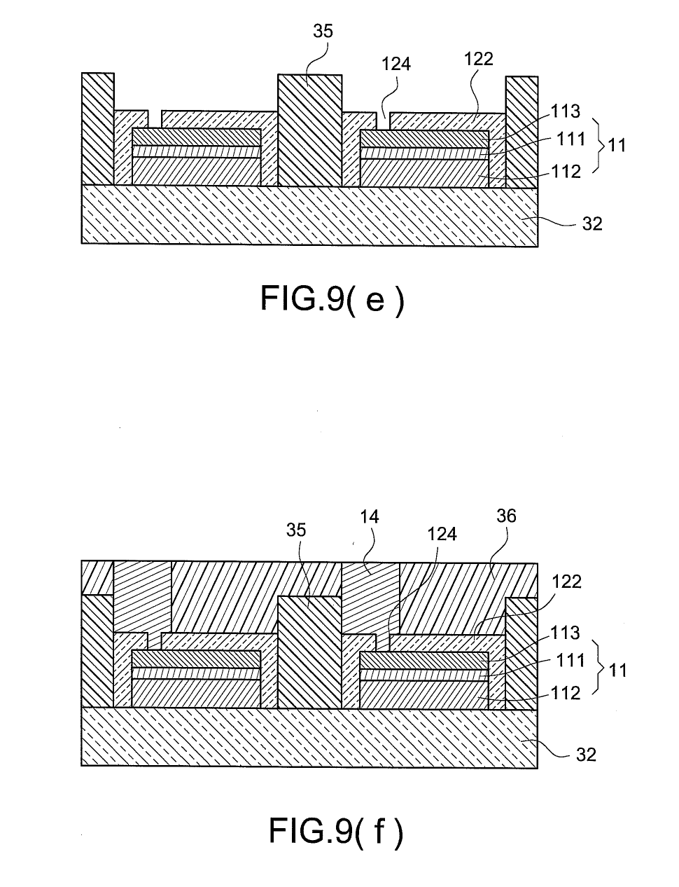

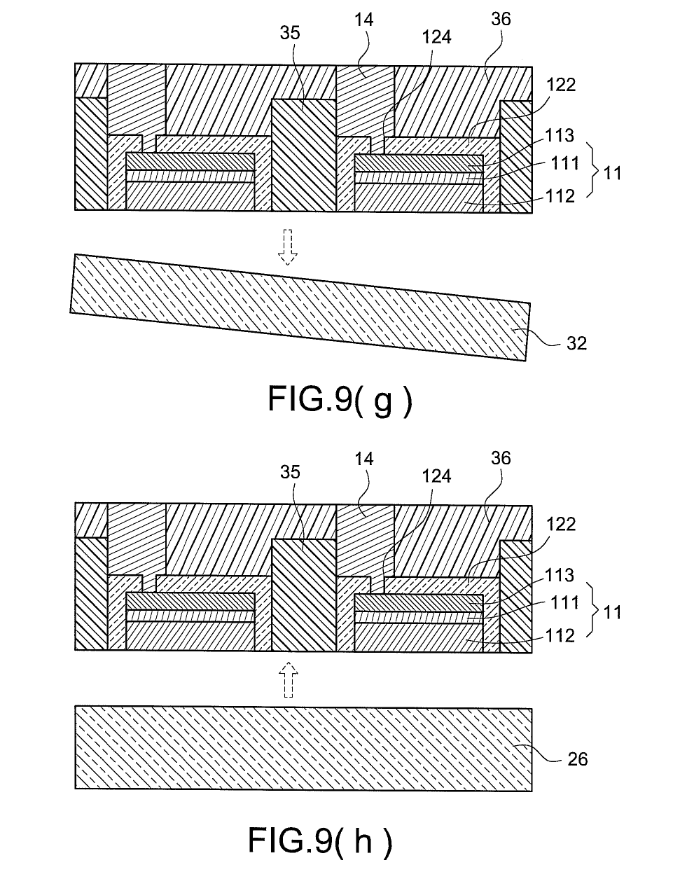

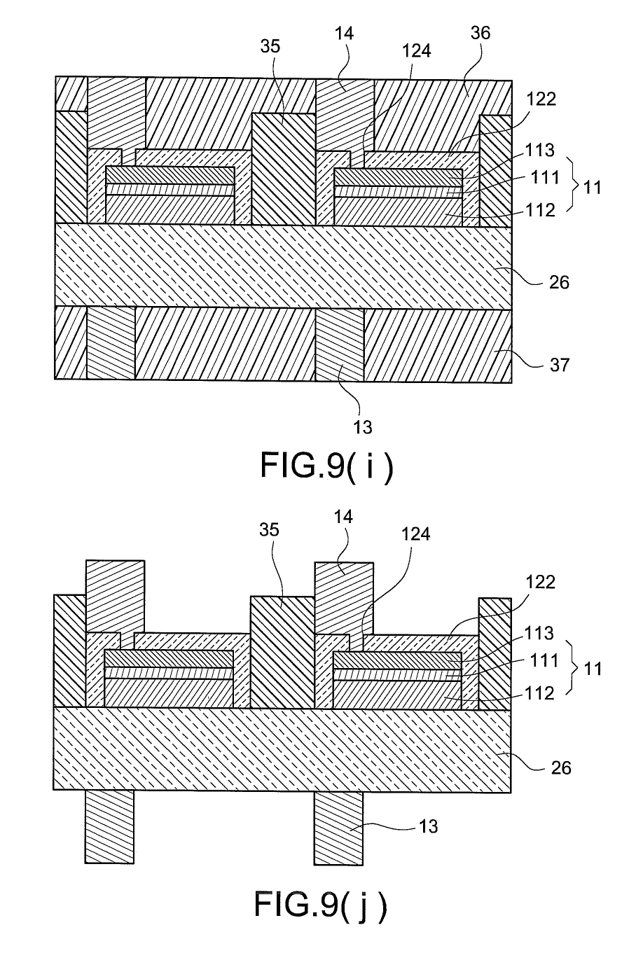

FIG. 9 discloses a method of fabricating LED element according to FIG. 8 detail as follow. As shown in FIG. 9(a), a first semiconductor layer 112, a light emitting active layer 111 and a second semiconductor layer 113 are epitaxially growing on a growing substrate 32 in sequence. The method of epitaxially growing may be but not limited to organic metal chemical vapor deposition or molecular beam epitaxy. Generally speaking, sapphire substrate is preferable used as the growing substrate 32 in consideration of lattice match.

Next, the epitaxial layers are etched by photolithography and etching process to obtain a plurality of the multi-layer semiconductor 11 located at the growing substrate 32 as shown in FIG. 9(b). The multi-layer semiconductor 11 has a first semiconductor layer 112 located on the growing substrate 32, a light emitting active layer 111 located on the first semiconductor layer 112 and a second semiconductor layer 113 located on the light emitting active layer 111.

Next, as shown in FIG. 9(c), a light transmissive insulator 122 is formed to cover the multi-layer semiconductor 11 by thin film process. Also, a second through hole 124 is formed in the light transmissive insulator 122 to expose the second semiconductor layer 113. As shown in FIG. 9(d), a first mask layer 33 is formed on the light transmissive insulator 122, and the region blocked by the first mask layer 33 corresponds to the light transmissive insulator 122. The first mask layer 15 may be made of but not limited to photoresist material by photolithography process. Next, the space 34 between the two multi-layer semiconductors 11 which are covered by the light transmissive insulator 122 is filled with spacers 35, as shown in FIG. 9(e). The spacers 35 surround the multi-layer semiconductors 11, and have a thickness greater than a thickness of the multi-layer semiconductors 11 which can fix and support the multi-layer semiconductors 11. The first mask layer 33 is removed after the spacer 35 is formed.

Next, as shown in FIG. 9(f), a second mask layer 36 is formed on the light transmissive insulator 122 and the spacers 35, and a second electrode 14 is formed by using the second mask layer 36. Next, as shown in FIG. 9(g), the growing substrate 32 is separated from the low surface of the multi-layer semiconductor 11 and the spacer 35. The separation may be achieved by but not limited to laser lift off or etching. The process can be further simplified by the spacer 35 fixing and supporting the multi-layer semiconductor 11 without using the temporary substrate.

Next, as shown in FIG. 9(h), a light transmissive conductive substrate 26 is bonded to the low surface of the multi-layer semiconductor 11 and the spacer 35. Next, the third mask layer 37 is formed on the low surface of the light transmissive conductive substrate 26, and the first electrodes 13 are formed by using the third mask layer 37, as shown in FIG. 9(i). The state of FIG. 9(j) is obtained after the second mask layer 36 and the third mask layer 37 are removed. At last, the LED element of FIG. 8 is obtained after the light transmissive conductive substrate 26 is cut.

It should be noted, in order to obtain a higher light transmission and electric conduction, it is required to change the growing substrate 32 to the light transmissive conductive substrate 26 because the light transmission of the growing substrate 32 is low in the above process of FIG. 9. However, when the growing substrate 32 is GaN substrate having a higher light transmission and electric conduction, that is to say, the growing substrate 32 is a light transmissive conductive substrate, the two steps of FIG. 9(g) of removing the growing substrate 32 and FIG. 9(h) of adhering the light transmissive conductive substrate 26 on the low surface of the multi-layer semiconductor 11 may be omitted to simplify the process.

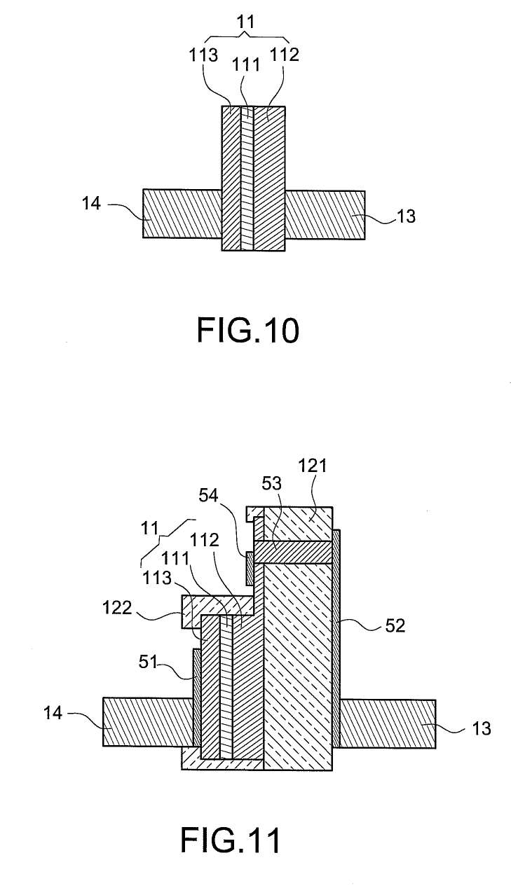

FIG. 10 shows an alternative example of an LED element according to the invention.

This example is different with the above examples by omitting the light transmissive substrate to electrically connect the first electrode 13 to the first semiconductor layer 112 directly. The method of fabricating the LED element can refer to FIG. 4(a). After removing the original light transmissive substrate 121, the first electrode 13 electrically connecting the first semiconductor layer 112 may be fabricated.

FIG. 11 shows another example of LED element according to the invention. The LED element is suitable to LED element having electrodes at the same side, that is to say, the electrode points 51, 54 are provided to face the same side of the multi-layer semiconductor 11 (as left side in the FIG. 11), and thus the electrode point 54 may electrically connect to the first electrode 13 provided on another side of the light transmissive substrate 121 by an electric conductive plug 53 (as right side in the FIG. 11) through the light transmissive substrate 121 to electrically connect to an extended portion 52. The electrode point 51 may electrically connect to the second electrode 14.

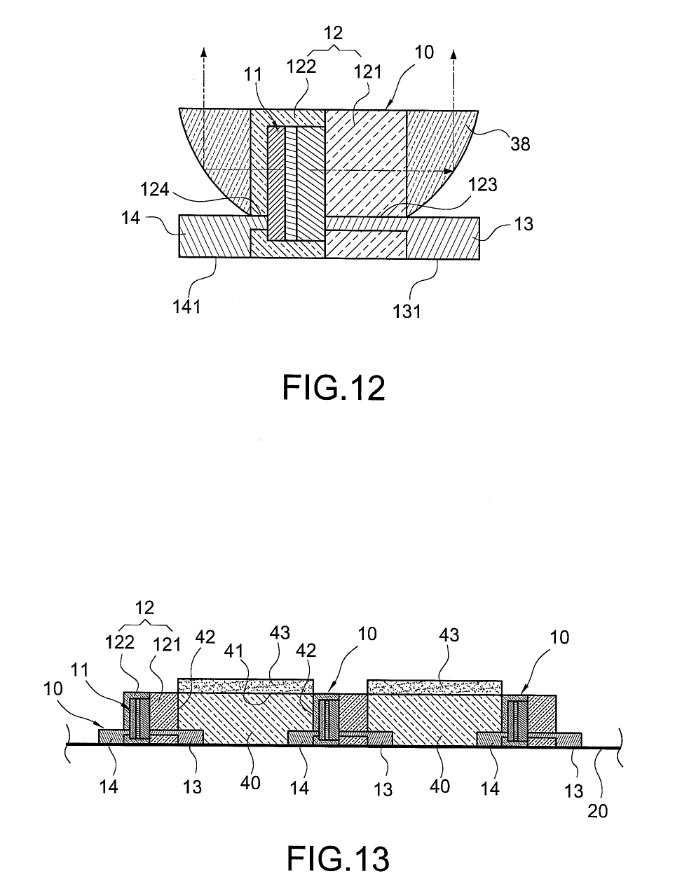

FIG. 12 shows another example of LED element according to the invention. This example is different with the above examples by including a light transmissive coating 38 surrounding an outside perimeter of the multi-layer semiconductor 11.

As shown in FIG. 13, the invention provides a light emitting device 100 for mounting on a predetermined surface 20. The light emitting device 100 comprises at least two LED elements 10 of the invention and a light guiding layer 40. The light guiding layer 40 is provided between two LED elements 10 on the predetermined surface 20. The light guiding layer 40 has a light emitting face 41 and two light incident faces 42 provided adjacent the light emitting face 41 facing two adjacent LED elements 10, 10 respectively.

Accordingly, the light emitted from LED elements 10 may enter the inside of light guiding layer 40 from two sides, transport in the light guiding layer 40 and emit from the light emitting face 41 to convert dot-likely light sources of the LED elements 10 to a face light source. Moreover, the light emitting device 100 may further include a phosphor layer 43 provided on the light emitting face 41 of light guiding layer 40 to convert the wavelength of the light emitted from the light emitting face 41. Alternatively, the light guiding layer 40 comprises phosphor material per se to convert the wavelength of the light.

The described examples are preferred examples of the invention. However, this is not intended to limit the scope of the invention. The equivalent changes and modifications may be made in accordance with the claims of the invention without departing from the scope of the invention.

What is claimed is:

1. A light emitting diode (LED) element for mounting on a predetermined surface, the LED element comprising:
a multi-layer semiconductor having a light emitting active layer substantially perpendicular to the predetermined surface, a first semiconductor layer and a second semiconductor layer respectively located on two opposite sides of the light emitting active layer;
a first electrode provided adjacent to and electrically connect to the first semiconductor layer, the first electrode having a first end surface facing the predetermined surface; and
a second electrode provided adjacent to and electrically connect to the second semiconductor layer, the second electrode having a second end surface facing the predetermined surface and the first end surface substantially aligning the second end surface, the first end surface and the second end surface directed to substantially locate on the same plane, wherein the first electrode and the second electrode are provided on two opposite sides of the multi-layer semiconductor.

2. The LED element of claim 1, further comprising a light transmissive substrate adjacent the first semiconductor layer, and the first electrode electrically connecting to the first semiconductor layer by the light transmissive substrate.

3. The LED element of claim 2, wherein a surface of the light transmissive substrate adjacent the first semiconductor layer is a texture surface.

4. The LED element of claim 1, further comprising a light transmissive insulator adjacent the second semiconductor layer, the light transmissive substrate having a first through hole to expose the first semiconductor layer, the light transmissive insulator having a second through hole to expose the second semiconductor layer, the first electrode connecting to the first semiconductor layer by the first through hole, and the second electrode connecting to the second semiconductor layer by the second through hole.

5. The LED element of claim 2, further comprising a light transmissive insulator covering the multi-layer semiconductor, the light transmissive substrate being a light transmissive conductive substrate, the light transmissive insulator having a through hole to expose the second semiconductor layer, the first electrode connecting to the first semiconductor layer by the light transmissive conductive substrate, and the second electrode connecting to the second semiconductor layer by the through hole.

6. The LED element of claim 4, wherein a surface of the second semiconductor layer adjacent the light transmissive insulator is a texture surface.

7. The LED element of claim 4, further comprising another multi-layer semiconductor adjacent the multi-layer semiconductor.

8. The LED element of claim 4, further comprising a light transmissive coating surrounding an outside perimeter of the multi-layer semiconductor.

9. The LED element of claim 2, wherein the light transmissive substrate is a growing substrate for epitaxially growing the multi-layer semiconductor thereon.

10. A light emitting device for mounting on a predetermined surface, the light emitting device comprising:
at least two LED elements separately provided on the predetermined surface, each LED element having a multi-layer semiconductor, a first electrode and a second electrode; the multi-layer semiconductor having a light emitting active layer substantially perpendicular to the predetermined surface, a first semiconductor layer and a second semiconductor layer respectively located on two opposite sides of the light emitting active layer, the first electrode provided adjacent to and electrically connect to the first semiconductor layer, the first electrode having a first end surface facing the predetermined surface, the second electrode provided adjacent to and electrically connect to the second semiconductor layer, the second electrode having a second end surface facing the predetermined surface and the first end surface substantially aligning the second end surface, the first end surface and the second end surface directed to substantially locate on the same plane, wherein the first electrode and the second electrode are provided on two opposite sides of the multi-layer semiconductor; and
a light guiding layer provided between two LED elements on the predetermined surface, the light guiding layer having a light emitting face and two light incident faces provided adjacent the light emitting face facing two adjacent LED elements respectively.

11. The light emitting device of claim 10, further comprising a light transmissive substrate adjacent the first semiconductor layer, and the first electrode electrically connecting to the first semiconductor layer by the light transmissive substrate.

12. The light emitting device of claim 11, wherein a surface of the light transmissive substrate adjacent the first semiconductor layer is a texture surface.

13. The light emitting device of claim 11, wherein the LED element further comprises a light transmissive insulator adjacent the second semiconductor layer, the light transmissive substrate having a first through hole to expose the first semiconductor layer, the light transmissive insulator having a second through hole to expose the second semiconductor layer, the first electrode connecting to the first semiconductor layer by the first through hole, and the second electrode connecting to the second semiconductor layer by the second through hole.

14. The light emitting device of claim 11, wherein the LED element further comprises a light transmissive insulator covering the multi-layer semiconductor, the light transmissive substrate being a light transmissive conductive substrate, the light transmissive insulator having a through hole to expose the second semiconductor layer, the first electrode connecting to the first semiconductor layer by the light transmissive conductive substrate, and the second electrode connecting to the second semiconductor layer by the through hole.

15. The light emitting device of claim 13, wherein a surface of the second semiconductor layer adjacent the light transmissive insulator is a texture surface.

16. The light emitting device of claim 13, wherein the LED element further comprises another multi-layer semiconductor adjacent the multi-layer semiconductor.

17. The light emitting device of claim 13, wherein the LED further comprises a light transmissive coating surrounding an outside perimeter of the multi-layer semiconductor.

18. The light emitting device of claim 11, wherein the light transmissive substrate is a growing substrate for directly epitaxially growing the multi-layer semiconductor thereon.

19. The light emitting device of claim 10, further comprising a phosphor layer provided on the light emitting face of the light guiding layer.

20. The light emitting device of claim 10, wherein the light guiding layer comprises a phosphor material.

21. A method for fabricating LED element comprising:
(a) epitaxially growing a multi-layer semiconductor on a light transmissive substrate, wherein the multi-layer semiconductor has a first semiconductor layer located on the light transmissive substrate, a light emitting active layer located on the first semiconductor layer and a second semiconductor layer located on the light emitting active layer;
(b) forming a light transmissive insulator to cover the multi-layer semiconductor;
(c) forming a first electrode to electrically connect the light transmissive substrate with the first semiconductor layer and forming a first end surface of the first electrode; and
(d) forming a second electrode to electrically connect the light transmissive insulator with the second semiconductor layer and forming a second end surface of the second electrode to align the first end surface, the first end surface and the second end surface directed to substantially locate on the same plane, wherein the first electrode and the second electrode are provided on two opposite sides of the multi-layer semiconductor.

22. The method for fabricating LED element of claim 21, wherein in step (c), forming a first through hole on the light transmissive substrate to expose the first semiconductor layer, the first electrode electrically connecting to the first semiconductor layer by the first through hole, and in step (d), forming a second through hole on the light transmissive insulator to expose the second semiconductor layer, the second electrode electrically connecting to the second semiconductor layer by the second through hole.

23. The method for fabricating LED element of claim 21, wherein in step (a), the light transmissive substrate being a light transmissive conductive substrate, the first electrode connecting to the first semiconductor layer by the light transmissive conductive substrate, and in step (d), forming a through hole on the light transmissive insulator to expose the second semiconductor layer, the second electrode connecting to the second semiconductor layer by the through hole.

24. The method for fabricating LED element of claim 21, wherein a texture surface is formed on the light transmissive substrate and the multi-layer semiconductor is epitaxially growing on the texture surface.

25. The method for fabricating LED element of claim 21, wherein a surface of the second semiconductor layer adjacent the light transmissive insulator is a texture surface.

26. A method for fabricating LED element comprising:
(a) epitaxially growing a multi-layer semiconductor on a growing substrate, wherein the multi-layer semiconductor has a first semiconductor layer located on the light transmissive substrate, a light emitting active layer located on the first semiconductor layer and a second semiconductor layer located on the light emitting active layer;
(b) forming a light transmissive insulator to cover the multi-layer semiconductor;
(c) replacing the growing substrate by a light transmissive substrate;
(d) forming a first electrode to electrically connect the light transmissive substrate with the first semiconductor layer and forming a first end surface of the first electrode;
(e) forming a second electrode to electrically connect the light transmissive insulator with the second semiconductor layer and forming a second end surface of the second electrode to align the first end surface, the first end surface and the second end surface directed to substantially locate on the same plane.

27. The method for fabricating LED element of claim 26, wherein in step (d), forming a first through hole on the light transmissive substrate to expose the first semiconductor layer, the first electrode electrically connecting to the first semiconductor layer by the first through hole, and in step (e), forming a second through hole on the light transmissive insulator to expose the second semiconductor layer, the second electrode electrically connecting to the second semiconductor layer by the second through hole.

28. The method for fabricating LED element of claim 26, wherein in step (c), the light transmissive substrate being a light transmissive conductive substrate, the first electrode connecting to the first semiconductor layer by the light transmissive conductive substrate, and in step (e), forming a through hole on the light transmissive insulator to expose the second semiconductor layer, the second electrode connecting to the second semiconductor layer by the through hole.

29. The method for fabricating LED element of claim 26, wherein a texture surface is formed on the light transmissive substrate and the multi-layer semiconductor is epitaxially growing on the texture surface.

30. The method for fabricating LED element of claim 26, wherein a surface of the second semiconductor layer adjacent the light transmissive insulator is a texture surface.
